(19) United States
(12) Patent Application Publication
(10) Pub. No.: US 2022/0157655 A1
(43) Pub. Date: May 19, 2022

(54) ELECTROPLATING WITH TEMPORARY FEATURES

(71) Applicant: Applied Materials, Inc., Santa Clara, CA (US)

(72) Inventor: Marvin L. Bernt, Whitefish, MT (US)

(73) Assignee: Applied Materials, Inc., Santa Clara, CA (US)

(21) Appl. No.: 16/952,343

(22) Filed: Nov. 19, 2020

(51) Int. Cl. H01L 21/768; H01L 21/033; C25D 3/00; C25D 7/12

(52) U.S. Cl. CPC H01L 21/76873; C25D 7/123; C25D 3/00; H01L 21/033

(57) ABSTRACT

Exemplary methods of electroplating may include forming a first mask layer on a semiconductor substrate. The methods may include forming a seed layer overlying the first mask layer. The methods may include forming a second mask layer overlying the seed layer. The methods may include plating an amount of metal on the semiconductor substrate. A portion of the metal may plate over the first mask layer.

### TECHNICAL FIELD

The present technology relates to electroplating operations in semiconductor processing. More specifically, the present technology relates to systems and methods that perform plating within permanent and dummy features in electroplating systems.

### BACKGROUND

Integrated circuits are made possible by processes which produce intricately patterned material layers on substrate surfaces. After formation, etching, and other processing on a substrate, metal or other conductive materials are often deposited or formed to provide the electrical connections between components. Because this metallization may be performed after many manufacturing operations, problems caused during the metallization may create expensive waste substrates or wafers.

Electroplating is performed in an electroplating chamber with the target side of the wafer in a bath of liquid electrolyte, and with electrical contacts on a contact ring touching a conductive layer, such as a seed layer, on the wafer surface. Electrical current is passed through the electrolyte and the conductive layer from a power supply. Metal ions in the electrolyte plate out onto the wafer, creating a metal layer on the wafer. When the wafer has a non-uniform distribution of contact structures for plating, current may not distribute uniformly to the substrate, and plating may occur at different rates across regions of the substrate. These variations can cause plating to be produced to different heights, which may further challenge downstream operations.

Thus, there is a need for improved systems and methods that can be used to produce high quality devices and structures. These and other needs are addressed by the present technology.

### SUMMARY

Exemplary methods of electroplating may include forming a first mask layer on a semiconductor substrate. The methods may include forming a seed layer overlying the first mask layer. The methods may include forming a second mask layer overlying the seed layer. The methods may include plating an amount of metal on the semiconductor substrate. A portion of the metal may plate over the first mask layer.

In some embodiments, the methods may include opening a portion of the first mask layer. The seed layer may form on the semiconductor substrate where the first mask layer is opened. The first mask layer may be opened over contact pads on the semiconductor substrate. The methods may include opening a portion of the second mask layer. The second mask layer may be opened in line with each opening formed in the first mask layer. The second mask layer may be opened in a location where the first mask layer remains. The methods may include, subsequent the plating, removing the second mask layer. The methods may include etching the seed layer. The methods may include removing the first mask layer. The portion of the metal plated over the first mask layer may be removed with the first mask layer. The first mask layer and the second mask layer may be or include photoresist. The portion of the metal plated on the first mask layer may be plated in a non-uniform pattern.

Some embodiments of the present technology may encompass methods of electroplating. The methods may include forming a first mask layer on a semiconductor substrate. The methods may include opening the first mask layer to expose contact locations defined on the semiconductor substrate. The methods may include forming a seed layer overlying the first mask layer. The seed layer may form a conductive coupling with each contact location defined on the semiconductor substrate. The methods may include plating an amount of metal on the semiconductor substrate. A portion of the metal may plate over the first mask layer.

In some embodiments, the methods may include forming a second mask layer overlying the seed layer. The methods may include opening a portion of the second mask layer. The second mask layer may be opened in line with each opening formed in the first mask layer. The second mask layer may be additionally opened in one or more locations exposing the seed layer and first mask layer. The methods may include, subsequent the plating, removing the second mask layer. The methods may include etching the seed layer. The methods may include removing the first mask layer. The portion of the metal plated over the first mask layer may be removed with the first mask layer.

Some embodiments of the present technology may encompass methods of electroplating. The methods may include forming a first mask layer on a semiconductor substrate. The methods may include forming a seed layer overlying the first mask layer. The methods may include forming a second mask layer overlying the seed layer. The methods may include opening the second mask layer. A portion of the semiconductor substrate may be exposed by the opening. The methods may include plating an amount of metal. A portion of the metal may plate over the first mask layer.

In some embodiments, the methods may include opening a portion of the first mask layer. The seed layer may form on the semiconductor substrate where the first mask layer is opened. The methods may include, subsequent the plating, removing the second mask layer. The methods may include etching the seed layer. The methods may include removing the first mask layer. The portion of the metal plated over the first mask layer may be removed with the first mask layer.

Such technology may provide numerous benefits over conventional technology. For example, the present technology may afford more uniform plating across a substrate. Additionally, the present technology may allow a tailored dummy profile that limits metal deposition while producing a more uniform deposition height. These and other embodiments, along with many of their advantages and features, are described in more detail in conjunction with the below description and attached figures.

### BRIEF DESCRIPTION OF THE DRAWINGS

A further understanding of the nature and advantages of the disclosed embodiments may be realized by reference to the remaining portions of the specification and the drawings.

FIG. 1 shows a schematic perspective view of an electroplating system according to some embodiments of the present technology.

FIG. 2 shows a partial cross-sectional view of an electroplating system according to some embodiments of the present technology.

FIGS. 3A-3B show schematic partial top views of a substrate during plating according to some embodiments of the present technology.

FIG. 4 shows exemplary operations in a method of electroplating according to some embodiments of the present technology.

FIGS. 5A-5I show schematic partial cross-sectional views of a substrate during plating according to some embodiments of the present technology.

FIGS. 6A-6B show schematic partial top views of a substrate during plating according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

Various operations in semiconductor manufacturing and processing are performed to produce vast arrays of features across a substrate. As layers of semiconductors are formed, vias, trenches, and other pathways are produced within the structure. These features may then be filled with a conductive or metal material that allows current to conduct through the device from layer to layer.

Electroplating operations may be performed to provide conductive material into vias and other features on a substrate. Electroplating utilizes an electrolyte bath containing ions of the conductive material to electrochemically deposit the conductive material onto the substrate and into the features defined on the substrate. The substrate on which metal is being plated operates as the cathode. An electrical contact, such as a ring or pins, may allow the current to flow through the system. During electroplating, a substrate may be clamped to a head and submerged in the electroplating bath to form the metallization. In systems as described below, the substrate may also be chucked within a seal that may be coupled with the head during processing.

As semiconductor structures become more complex, plating operations may cover vast arrays along a substrate, which may include densely populated areas as well as more sparsely populated regions. Electroplating baths may provide a more uniform current density across the substrate, and thus more sparsely populated regions for plating may plate differently from more densely populated regions. For example, in regions with further spaced features for plating, regions where there are no feature landings on a barrier layer may cause current to bunch towards the nearest features. This may cause plating to occur at different rates, where plating may occur at an increased rate in less dense feature regions.

Subsequent fabrication operations may include coupling the substrate with an additional substrate, which may often be characterized by a substantially flat profile. When conductive features formed in plating extend to different heights, regions with shorter heights may not fully contact coupling locations on a second substrate. Conventional technologies have attempted to address these issues in multiple ways. For example, conventional plating may form permanent dummy features across the substrate to produce a more uniform plating pattern. However, this may have limited applicability. As the dummy features formed in open regions will be permanent, this approach may not be applicable for substrate configurations where subsequent device placement may be performed. For example, where subsequent processing may locate a die, the substrate may need to be maintained free of dummy features, and thus such permanent dummy placement may not be possible.

Alternatively, conventional technologies may attempt to overcome the height discontinuity during subsequent joining operations. For example, when the substrate is joined with a second substrate, solder may be disposed on the conductive features to facilitate the conductive contact. Some conventional technologies may increase an amount of solder to overcome height differentials between features. Although this may accommodate shorter heights, the solder applied may be excessive for greater height features, and may be expressed outward from the feature during joining. As pitch between features continues to be reduced, this additional solder may express to a great enough degree to bridge adjacent features, which may cause shorts along the device leading to damage of the structures formed.

The present technology may overcome these issues by producing dummy features that may be temporary in nature. By forming removable dummy features, the present technology may afford current control among different plating regions across the substrate, which may allow more consistent plating heights between features. After describing an exemplary chamber system in which embodiments of the present technology may be performed, the remaining disclosure will discuss aspects of the systems and processes of the present technology.

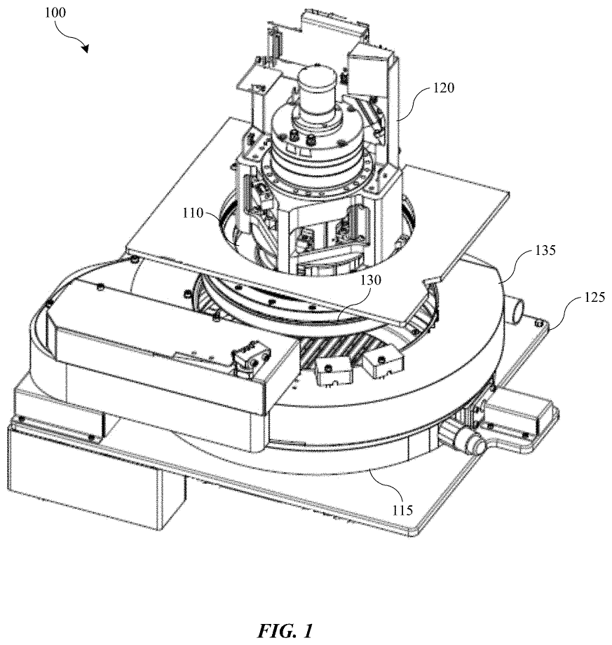

FIG. 1 shows a schematic perspective view of an electroplating system 100 for which methods and cleaning systems may be utilized and practiced according to embodiments of the present technology. Electroplating system 100 illustrates an exemplary electroplating system including a system head 110 and a bowl 115. During electroplating operations, a wafer may be clamped to the system head 110, inverted, and extended into bowl 115 to perform an electroplating operation. Electroplating system 100 may include a head lifter 120, which may be configured to both raise and rotate the head 110, or otherwise position the head within the system including tilting operations. The head and bowl may be attached to a deck plate 125 or other structure that may be part of a larger system incorporating multiple electroplating systems 100, and which may share electrolyte and other materials. A rotor may allow a substrate clamped to the head to be rotated within the bowl, or outside the bowl in different operations. The rotor may include a contact ring, which may provide the conductive contact with the substrate. A seal 130 discussed further below may be connected with the head. Seal 130 may include a chucked wafer to be processed. FIG. 1 illustrates an electroplating chamber that may include components to be cleaned directly on the platform. Although it is to be understood that other configurations are possible, including platforms on which the head is moved to an additional module and seal or other component cleaning is performed, an exemplary in situ rinse system 135 is also illustrated with the system 100.

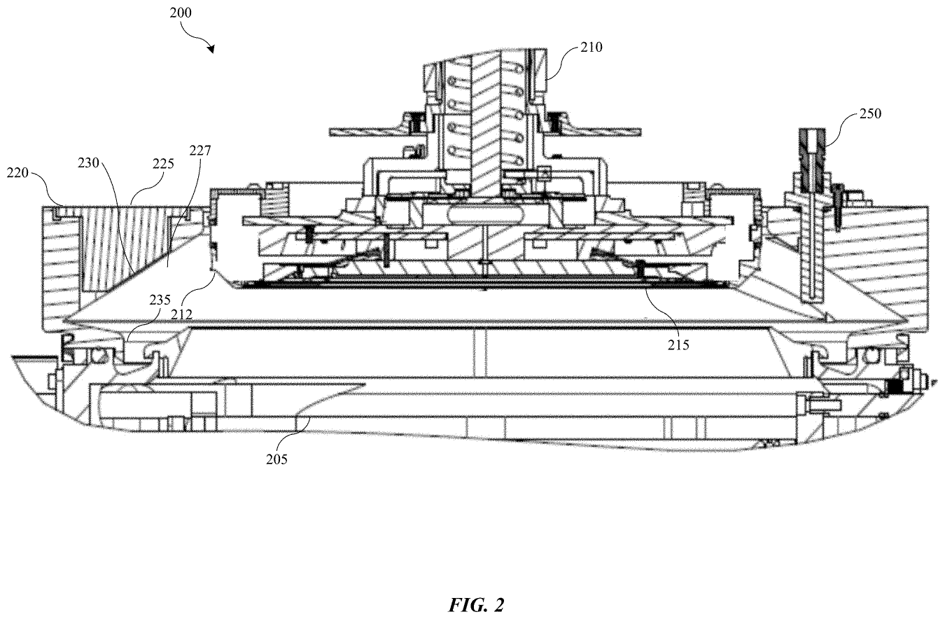

Turning to FIG. 2 is shown a partial cross-sectional view of a chamber including aspects of an electroplating apparatus 200 according to some embodiments of the present technology. The electroplating apparatus 200 may be incorporated with an electroplating system, including system 20 described above. As illustrated in FIG. 2, a plating bath vessel 205 of an electroplating system is shown along with a head 210 having a substrate 215 coupled with the head. The substrate may be coupled with a seal 212 incorporated on the head in some embodiments. A rinsing frame 220 may be coupled above the plating bath vessel 205, and may be configured to receive the head into the vessel during plating. Rinsing frame 220 may include a rim 225 extending circumferentially about an upper surface of the plating bath vessel 205. A rinsing channel 227 may be defined between the rim 225 and an upper surface of the plating bath vessel 205. For example, rim 225 may include interior sidewalls 230 characterized by a sloping profile. As described above, rinse fluid slung off a substrate may contact the sidewalls 230, and may be received in a plenum 235 extending about the rim for collection of the rinse fluid from the electroplating apparatus 200.

Electroplating apparatus 200 may additionally include one or more cleaning components in some embodiments. The components may include one or more nozzles used to deliver fluids to or towards the substrate 215 or the head 210. FIG. 2 illustrates one of a variety of embodiments in which improved rinse assemblies may be used to protect the bath and substrate during rinsing operations. A side clean nozzle 250 may extend through the rim 225 of the rinsing frame 220 in some embodiments and be directed to rinse seal 212, along with aspects of substrate 215.

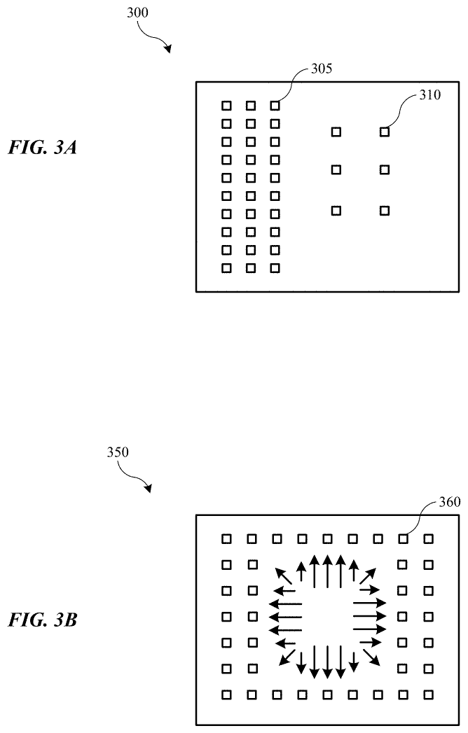

As previously noted, the present technology may produce more uniform plating across substrates having non-uniform contact distributions across a substrate. FIG. 3A may show a schematic partial top view of a substrate 300 during plating according to some embodiments of the present technology. As previously described, some substrates may include regions with more dense plating requirements, as well as less dense plating requirements. In regions having contacts such as contact 305, plating may occur uniformly at each location. However, at contacts 310, the contact locations may be spaced such that localized regions may be limited to these contacts, which may cause current to divert towards these locations. This may cause an increase in current at these locations, which may increase plate out from the electroplating bath. Consequently, plating may increase in these locations.

Similarly, FIG. 3B illustrates a substrate 350 having a configuration in which plating sections extend about a location where no plating may occur. As shown, plating locations 360 may extend about a central location where no plating is to occur. For example, subsequent processing may locate a die in this location, and thus the region may be intended to remain blank during plating. This region where no plating may occur may impact plating in other locations. Current distribution may be relatively uniform in the electroplating bath, and thus in regions where no plating may occur, current may follow paths towards regions where plating may occur, which may cause plating to occur at an increased rate. Accordingly, plating locations adjacent regions where no plating may occur may be characterized by increased plating, which may cause any of the issues as previously described. The present technology may form dummy features that limit these plating non-uniformities.

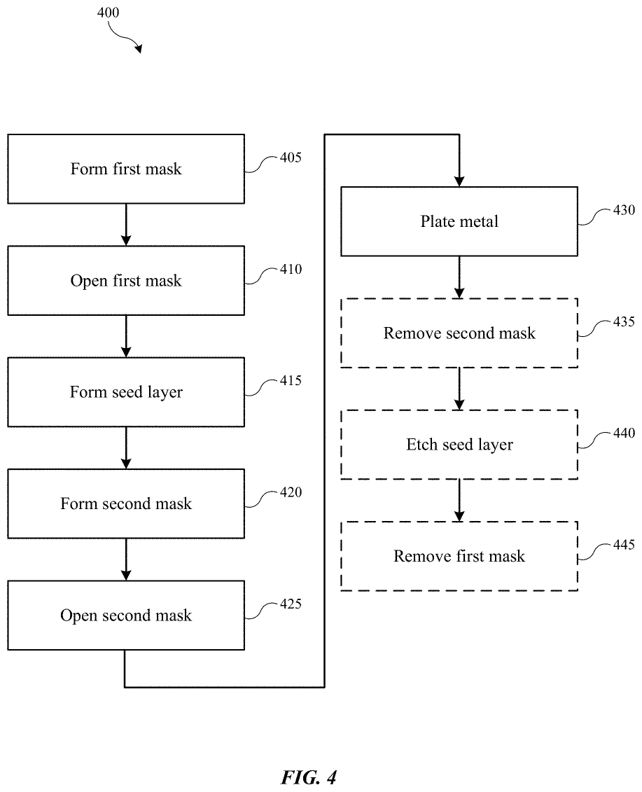

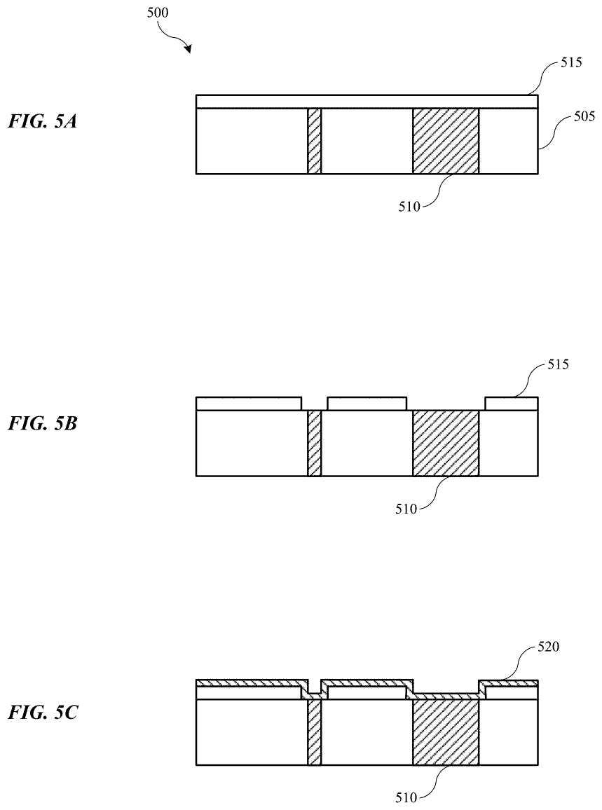

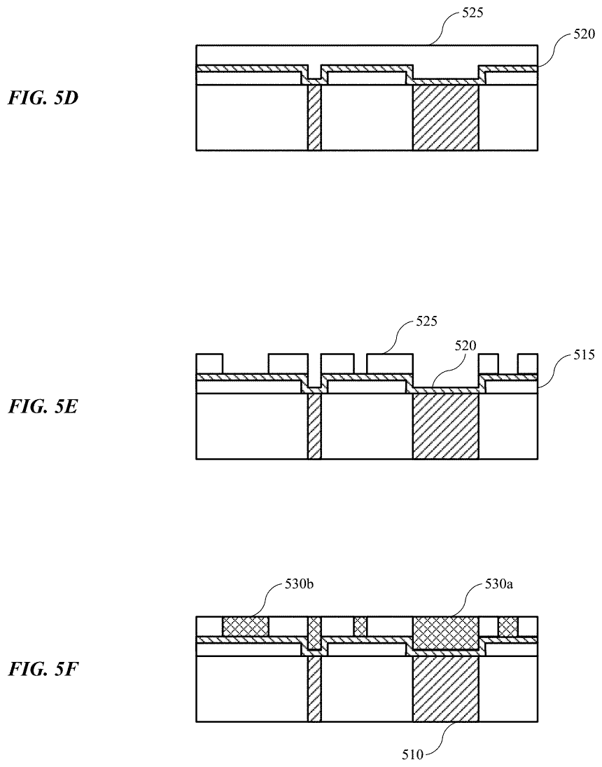

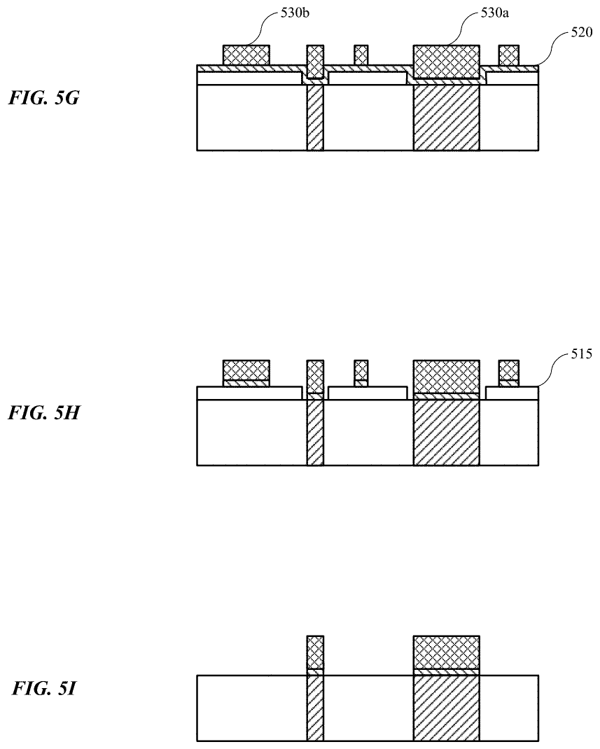

The chamber or systems discussed previously may be used in performing exemplary methods including electroplating methods. Turning to FIG. 4 is shown exemplary operations in a method 400 according to embodiments of the present technology. Method 400 may include one or more operations prior to the initiation of the method, including front end processing, deposition, gate formation, etching, polishing, cleaning, or any other operations that may be performed prior to the described operations. The method may include a number of optional operations, which may or may not be specifically associated with some embodiments of methods according to the present technology. For example, many of the operations are described in order to provide a broader scope of the processes performed, but are not critical to the technology, or may be performed by alternative methodology as will be discussed further below. Method 400 may describe operations shown schematically in FIGS. 5A-5I, the illustrations of which will be described in conjunction with the operations of method 400. It is to be understood that the figures illustrate only partial schematic views, and a substrate may contain any number of additional materials and features having a variety of characteristics and aspects as illustrated in the figures.

Method 400 may or may not involve optional operations to develop the semiconductor structure 500 to a particular fabrication operation. It is to be understood that method 400 may be performed on any number of semiconductor structures or substrates 505, as illustrated in FIG. 5A, including exemplary structures on which electroplating operations may be performed. Exemplary semiconductor structures may include a trench, via, or other recessed features that may include one or more materials. For example, an exemplary substrate may contain silicon, silicon oxide, or some other semiconductor substrate material as well as interlayer dielectric materials through which a recess, trench, via, or isolation structure may be formed. In some embodiments exemplary substrates may include contact structures 510, which may provide conductive coupling to transistors or other structures formed through the substrate. Substrate 505 may be masked during processes according to embodiments of the present technology to perform plating at these contact structures.

At operation 405, a mask layer may be formed over the semiconductor substrate, and which may be a global mask formed across the substrate. As illustrated in FIG. 5A, the mask 515 may be formed over the entire substrate including regions to be plated as well as regions to remain unplated. The mask may be formed of any number of materials, and may be a photoresist in some embodiments. The mask may be formed over all regions in which plating is intended to occur, as well as over regions in which plating is intended to be avoided. To limit effects on seed layer formation, the mask layer 515, which may be a first mask layer, may be formed to a thickness of less than or about 25 μm, and may be formed to a thickness of less than or about 20 μm, less than or about 15 μm, less than or about 10 μm, less than or about 5 μm, less than or about 3 μm, less than or about 1 μm, or less.

At operation 410, an opening process may be performed to pattern the mask. For example, a lithographic opening may be performed to pattern the photoresist and open regions of the mask. As illustrated in FIG. 5B, the opening may be performed about regions where the contact structures 510 may be formed through the substrate, such as about contact pads at the substrate surface. In some embodiments the openings may be formed at equal dimensions to the contact pads, or may be formed wider than the contact pad distances as illustrated. Subsequently, at operation 415, a seed layer may be formed across the semiconductor substrate. As shown in FIG. 5C, seed layer 520 may be formed overlying the first mask layer as well as over the exposed substrate surface where the first mask layer has been opened. By maintaining the first mask layer thickness at reduced height, the formation may be facilitated. For example, the seed layer may be formed by physical vapor deposition, and may be formed to a uniform thickness across the substrate, and may conformally extend across the first mask layer 510 as well as across the contact locations on the substrate. Accordingly, a conductive path may be formed between the contact structures 510 and the seed layer 520.

In embodiments according to the present technology, method 400 may include forming a second mask layer at operation 420. The second mask layer may also be formed of any number of materials, and may be a photoresist layer in some embodiments of the present technology. As illustrated in FIG. 5D, second mask layer 525 may be formed globally across the substrate as well, and may extend fully across the substrate surface or seed layer 520. A patterning operation may be performed at operation 425 to open the second mask in a number of regions. While the first opening operation of the first mask layer may open the mask only at locations where contact structures may be formed through the substrate, the opening operation for the second mask layer may be performed both at locations where structures may be formed through the substrate, as well as dummy locations across the substrate.

As illustrated in FIG. 5E, second mask layer 525 may be opened at each location where first mask layer 515 may be opened, as well as at additional locations where first mask layer 515 is maintained. Second mask layer 525 may be opened in line with each opening formed in the first mask layer 515, and may be opened similarly as the first mask layer, or may be opened to a reduced width. For example, and as illustrated, while first mask layer 515 may be opened to accommodate the seed layer 520, the second mask layer may be opened to a reduced thickness, which may account for sidewall coverage of the seed layer. The difference between the first mask layer openings and the second mask layer openings may be equal to the thickness of the seed layer in some embodiments, which may be less than or about 1 μm, and may be less than or about 900 nm, less than or about 800 nm, less than or about 700 nm, less than or about 600 nm, less than or about 500 nm, less than or about 400 nm, less than or about 300 nm, less than or about 200 nm, less than or about 100 nm, less than or about 50 nm, or less. During subsequent removal and etching operations as will be described below, this thickness differential may limit additional seed layer residue about features formed from the substrate during plating operations.

At operation 430, plating may be performed across the substrate. Plating may occur with any metals used in plating operations in semiconductor processing, including copper and any other metals that may be plated in electroplating operations. By creating additional openings across the second mask layer, plating may occur at desired locations across the substrate to a uniform thickness. The operations of method 400 may allow dummy features to be formed across the substrate, which as will be explained further below may be formed temporarily across the substrate. Because the seed layer may be formed overlying the first mask layer, any plating formed through the second mask layer may extend from the seed layer, whether overlying the first mask material, or through the first and second mask materials to extend to the substrate contact locations. As illustrated in FIG. 5F, a portion of the plating 530 may occur at regions 530a where the plating may extend to the seed layer electrically coupled with the contact structures 510. Additionally, based on the patterning of the second mask layer, a portion of the plating 530 may also occur where patterning was not performed on the first mask layer, such as at regions 530b. Accordingly, in these regions, the plating may extend over the first mask layer, and may not contact the substrate. Consequently, by producing the two mask structures, plating may be performed at designated permanent regions, such as where substrate contact pads are formed, as well as at dummy locations overlying the first mask material. Unlike some conventional technologies, the dummy locations may not be in contact with the substrate underlying the first mask structure.

Once the plating has occurred with the multiple mask structure according to some embodiments of the present technology, a number of optional operations may be performed to produce a more uniform plating formation across the substrate. For example, in some embodiments, at optional operation 435 the second mask material may be stripped from the substrate. The removal may be a selective removal or a photoresist removal, which may remove the material from the substrate and about the plated material formed along the substrate. As shown in FIG. 5G, regions 530a and 530b may all be exposed during the removal. Because each structure may be formed overlying the seed layer 520, all sections may remain after removal of the second mask layer.

Subsequent the second mask layer removal, the seed layer may be etched from the substrate at optional operation 440. The etching operation may be a wet etch or selective etch to remove the metal material across the substrate to segregate the contact regions about the substrate. Additionally, the etching may expose the first mask layer beneath the seed layer. As illustrated in FIG. 5H, the seed layer may be removed in a metal-selective etch. As discussed previously, because the first mask layer 515 may have been patterned with wider openings than the second mask layer, the seed layer may be recessed to regions specifically beneath plated regions and specifically overlying contact pads. Accordingly, by forming the first and second mask layers to different widths, the seed layer may be controlled and permanent formations may be formed to similar thicknesses as the pad regions formed along the substrate.

At optional operation 445, the first mask layer may be stripped from the semiconductor substrate. Because the dummy structures may be formed overlying the first mask layer, the dummy structures may be removed from the substrate at optional operation 445. As illustrated in FIG. 5I, the remaining structure may include formation to a target or designated height across the substrate, including at locations of more dense and less dense patterning. By producing an amount of dummy formation overlying a mask region, plating may be controlled across a substrate, and may produce substrates having controlled height across any number of regions across a substrate. Additionally, by forming the dummy features over a mask section, the dummy features may be removed from the substrate, which may facilitate or allow access for substrate processes where access to the substrate may be benefited.

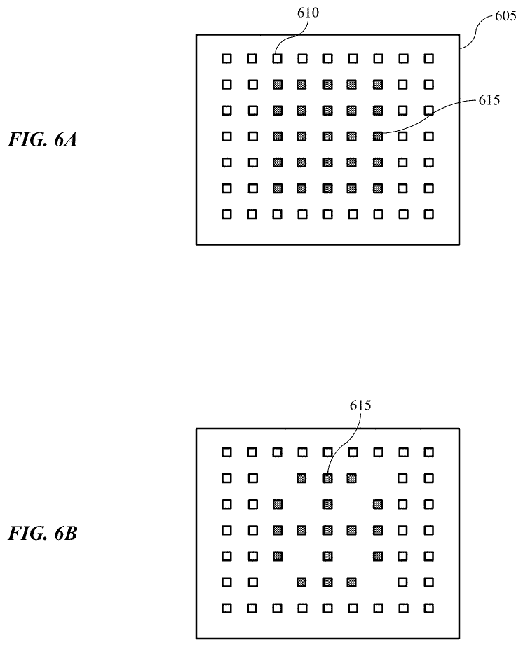

FIGS. 6A-6B show schematic partial top views of a substrate during plating according to some embodiments of the present technology. As explained previously, by producing temporary dummy features, plating height for permanent features may be improved, and may be produced more uniformly across a substrate, regardless of plating density at various locations across the substrate. Accordingly, the present technology may improve plating operations, although additional plating in dummy regions may be performed. However, in some embodiments, the present technology may also limit the amount of metal consumed by dummy features.

As illustrated in FIG. 6A, a substrate 605 may be characterized by a region in which plating may not be desired, as previously described. By utilizing methods according to the present technology, plating may be performed in permanent locations 610, as well as dummy locations 615. As shown in the figure, the dummy locations may be formed in a pattern to produce a uniform overall pattern across the substrate. This may ensure uniform plating in desired locations, although this may occur at the cost of scrap plating. However, in some embodiments, when the first mask layer is removed, a filtering operation may be performed to separate the dummy plating structures, which may be recycled for subsequent plating.

Additionally, in some embodiments additional control may be performed to further limit the amount of dummy plating that may occur. As shown in FIG. 6B, the dummy patterning may be produced based on current distribution during plating, and may be formed in a non-uniform pattern across blank sections or less densely populated sections of the substrate. For example, dummy locations 615 may be formed in a pattern where locations that may receive increased current distribution may be adjacent an increased number of dummy locations, and locations where reduced current distribution may occur may not include additional dummy locations. Accordingly, additional plating at dummy locations may be minimized, while producing plating at permanent locations characterized by a more uniform height. Consequently, plating across permanent features may be controlled to a target height across all features that may be maintained within a variation of less than or about 20%, and may be maintained within a height variation of less than or about 15%, less than or about 10%, less than or about 5%, less than or about 3%, less than or about 1%, or less. By producing controlled dummy structures overlying a separate mask layer, the present technology may more accurately control plating height across complex structures on a substrate.

In the preceding description, for the purposes of explanation, numerous details have been set forth in order to provide an understanding of various embodiments of the present technology. It will be apparent to one skilled in the art, however, that certain embodiments may be practiced without some of these details, or with additional details. For example, other substrates that may benefit from the wetting techniques described may also be used with the present technology.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included. Where multiple values are provided in a list, any range encompassing or based on any of those values is similarly specifically disclosed.

As used herein and in the appended claims, the singular forms “a”, “an”, and “the” include plural references unless the context clearly dictates otherwise. Thus, for example, reference to “a material” includes a plurality of such materials, and reference to “the feature” includes reference to one or more features and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A method of electroplating, the method comprising:
forming a first mask layer on a semiconductor substrate;
forming a seed layer overlying the first mask layer;
forming a second mask layer overlying the seed layer; and
plating an amount of metal on the semiconductor substrate, wherein a portion of the metal plates over the first mask layer.

2. The method of electroplating of claim 1, further comprising:
opening a portion of the first mask layer, wherein the seed layer forms on the semiconductor substrate where the first mask layer is opened.

3. The method of electroplating of claim 2, wherein the first mask layer is opened over contact pads on the semiconductor substrate.

4. The method of electroplating of claim 2, further comprising:
opening a portion of the second mask layer, wherein the second mask layer is opened in line with each opening formed in the first mask layer, and wherein the second mask layer is opened in a location where the first mask layer remains.

5. The method of electroplating of claim 1, further comprising:
subsequent the plating, removing the second mask layer.

6. The method of electroplating of claim 5, further comprising:
etching the seed layer.

7. The method of electroplating of claim 6, further comprising:
removing the first mask layer, wherein the portion of the metal plated over the first mask layer is removed with the first mask layer.

8. The method of electroplating of claim 1, wherein the first mask layer and the second mask layer comprise photoresist.

9. The method of electroplating of claim 1, wherein the portion of the metal plated on the first mask layer is plated in a non-uniform pattern.

10. A method of electroplating, the method comprising:
forming a first mask layer on a semiconductor substrate;
opening the first mask layer to expose contact locations defined on the semiconductor substrate;
forming a seed layer overlying the first mask layer, wherein the seed layer forms a conductive coupling with each contact location defined on the semiconductor substrate; and
plating an amount of metal on the semiconductor substrate, wherein a portion of the metal plates over the first mask layer.

11. The method of electroplating of claim 10, further comprising:
forming a second mask layer overlying the seed layer.

12. The method of electroplating of claim 11, further comprising:
opening a portion of the second mask layer, wherein the second mask layer is opened in line with each opening formed in the first mask layer.

13. The method of electroplating of claim 12, wherein the second mask layer is additionally opened in one or more locations exposing the seed layer and first mask layer.

14. The method of electroplating of claim 12, further comprising:
subsequent the plating, removing the second mask layer.

15. The method of electroplating of claim 14, further comprising:
etching the seed layer.

16. The method of electroplating of claim 15, further comprising:
removing the first mask layer, wherein the portion of the metal plated over the first mask layer is removed with the first mask layer.

17. A method of electroplating, the method comprising:
forming a first mask layer on a semiconductor substrate;
forming a seed layer overlying the first mask layer;
forming a second mask layer overlying the seed layer;
opening the second mask layer, wherein a portion of the semiconductor substrate is exposed by the opening; and
plating an amount of metal, wherein a portion of the metal plates over the first mask layer.

18. The method of electroplating of claim 17, further comprising:
opening a portion of the first mask layer, wherein the seed layer forms on the semiconductor substrate where the first mask layer is opened.

19. The method of electroplating of claim 17, further comprising:
subsequent the plating, removing the second mask layer; and
etching the seed layer.

20. The method of electroplating of claim 19, further comprising:
removing the first mask layer, wherein the portion of the metal plated over the first mask layer is removed with the first mask layer.
